(19) United States
(12) Patent Application Publication
(10) Pub. No.: US 2020/0192154 A1
(43) Pub. Date: Jun. 18, 2020

(54) Display Substrate and Manufacturing Method Therefor, Display Panel, and Display Device

(71) Applicants: Hefei Xinsheng Optoelectronics Technology Co., Ltd., Hefei (CN); BOE Technology Group Co., Ltd., Beijing (CN)

(72) Inventors: Liangliang Jiang, Beijing (CN); Lei Guo, Beijing (CN)

(73) Assignees: Hefei Xinsheng Optoelectronics Technology Co., Ltd., Hefei (CN); BOE Technology Group Co., Ltd., Beijing (CN)

(21) Appl. No.: 16/643,295

(22) PCT Filed: Mar. 25, 2019
(86) PCT No.: PCT/CN2019/079517

§ 371 Date: Feb. 28, 2020

(30) Foreign Application Priority Data
Mar. 26, 2018 (CN) 201810252544.5

(51) Int. Cl. G02F 1/1335; H01L 27/12; G02F 1/1362

(52) U.S. Cl. CPC G02F 1/133528; H01L 27/124; G02F 1/133514; G02F 2001/133531; G02F 1/133512; G02F 2001/133548; G02F 2001/133565; G02F 1/136286

(57) ABSTRACT

Embodiments of the present disclosure provide a display substrate, a display panel, a display device and a manufacturing method thereof. The display substrate includes a base substrate and a metal wire grating layer on the base substrate. The metal wire grating layer includes a plurality of metal wire grating units, and polarization directions of the plurality of metal wire grating units are different.

This application claims the benefit of Chinese patent application No. 201810252544.5 filed on Mar. 26, 2018, which is hereby entirely incorporated by reference as a part of the present application.

### TECHNICAL FIELD

Embodiments of the present disclosure relate to a display substrate, a manufacturing method of the display substrate, a display panel and a display device.

### BACKGROUND

In recent years, the three-dimensional display technology has been widely concerned and used because it can realize stereoscopic display of an image.

The three-dimensional display technology includes a polarized three-dimensional display technology. A principle of the polarized three-dimensional display technology is as follows: a display panel processes an image into two sets of pictures with different polarization directions, a user wears 3D glasses so that left and right eyes of the user respectively acquire the two sets of pictures with the different polarization directions, and the user's brain synthesizes the two sets of pictures to obtain the image with a stereoscopic display effect.

In a situation where a liquid crystal display panel is manufactured by using the polarized three-dimensional display technology, a layer of polarizer with two polarization directions is attached to each of a light incident side and a light emitting side of the liquid crystal display panel. Because the polarizer is mainly made by using a stretching process, the polarizer with two polarization directions has disadvantages of complex production process and high production cost, resulting in that the display panel using the polarizer also has the disadvantages of complex production process and high production cost.

### SUMMARY

According to the embodiments of the present disclosure, a display substrate is provided. The display substrate includes a base substrate and a metal wire grating layer on the base substrate, the metal wire grating layer comprises a plurality of metal wire grating units, and polarization directions of the plurality of metal wire grating units are different.

For example, the plurality of metal wire grating units are arranged in an array, and the polarization direction of each metal wire grating unit is different from the polarization direction of an adjacent metal wire grating unit that each metal wire grating unit is adjacent to.

For example, the polarization direction of each metal wire grating unit is perpendicular to the polarization direction of the adjacent metal wire grating unit that each metal wire grating unit is adjacent to.

For example, the plurality of metal wire grating units are arranged in an array, the metal wire grating units in a first direction have a same polarization direction, adjacent metal wire grating units among the metal wire grating units in a second direction have different polarization directions, and the first direction and the second direction are perpendicular to each other.

For example, the polarization directions of the adjacent metal wire grating units among the metal wire grating units in the second direction are perpendicular to each other.

For example, the polarization direction of each metal wire grating unit is parallel or perpendicular to a horizontal direction.

For example, the polarization direction of each metal wire grating unit is at a position of constituting an acute angle with respect to a horizontal direction.

According to the embodiments of the present disclosure, a display panel is provided. The display panel includes a first display substrate and a second display substrate which are opposite to each other and are bonded to each other. Each of the first display substrate and the second display substrate is the display substrate as described above. Orthographic projections of the plurality of metal wire grating units of the first display substrate on the second display substrate respectively overlap the plurality of metal wire grating units of the second display substrate in a one-to-one manner, and the polarization directions of the metal wire grating unit of the first display substrate and the metal wire grating unit of the second display substrate which directly face each other are perpendicular to each other.

For example, the first display substrate is a color filter substrate, the color filter substrate further includes a black matrix and a color filter layer, the color filter layer includes a plurality of color filter units arranged in an array, and each color filter unit of the color filter layer is in a color filter region surrounded by the black matrix; and orthographic projections of the plurality of color filter units on the metal wire grating layer respectively overlap the plurality of metal wire grating units in a one-to-one manner.

For example, the black matrix, the color filter layer and the metal wire grating layer are on a same side of the color filter substrate, and the plurality of color filter units of the color filter layer respectively cover the plurality of metal wire grating units of the metal wire grating layer.

For example, the black matrix and the color filter layer are on a first side of the color filter substrate facing the second display substrate, the metal wire grating layer is on a second side of the color filter substrate, and the first side and the second side are opposite sides.

For example, the second display substrate is an array substrate, the array substrate further includes a pixel layer, the pixel layer includes a plurality of pixel units arranged in an array, and orthographic projections of the plurality of pixel units on the metal wire grating layer respectively overlap the plurality of metal wire grating units in a one-to-one manner.

For example, the pixel layer and the metal wire grating layer are on a same side of the array substrate, and the plurality of pixel units of the pixel layer respectively cover the plurality of metal wire grating units of the metal wire grating layer.

For example, the pixel layer is on a first side of the array substrate facing the first display substrate, the metal wire grating layer is on a second side of the array substrate, and the first side and the second side are opposite sides.

For example, the array substrate further includes a plurality of gate wires and a plurality of data wires, the plurality of gate wires and the plurality of data wires cross each other to define the plurality of pixel units, and the metal wire grating layer is in a layer where the plurality of gate wires or the plurality of data wires are located.

For example, among the plurality of metal wire grating units of the array substrate, an extension direction of metal wires in a part of the plurality of the metal wire grating units is parallel to the plurality of gate wires, and an extension direction of metal wires in another part of the plurality of the metal wire grating units is parallel to the plurality of data wires.

According to the embodiments of the present disclosure, a display device is provided. The display device includes the display panel as described above.

According to the embodiments of the present disclosure, a manufacturing method of the display substrate as described above is provided. The manufacturing method includes: providing the base substrate; and forming the metal wire grating layer on the base substrate through a patterning process.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is a schematic structural diagram of a display substrate provided by embodiments of the present disclosure;

FIG. 2 is another schematic structural diagram of the display substrate provided by the embodiments of the present disclosure;

FIG. 3 is a schematic structural diagram of a display panel according to the embodiments of the present disclosure;

FIG. 4 is a flowchart of a manufacturing method of the display substrate according to the embodiments of the present disclosure;

FIG. 5 is a schematic diagram of a three-dimensional structure of the display substrate provided by the embodiments of the present disclosure; and

FIG. 6 is a schematic diagram illustrating distribution of a plurality of pixel units according to the embodiments of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

In the embodiments of the present disclosure, unless otherwise stated, the meaning of “plurality” is two or more; orientations or positional relationships indicated by the terms “upper”, “lower”, “left”, “right”, “inside”, “outside” and the like are based on the orientations or positional relationships shown in the drawings, are only for the convenience of describing the embodiments of the present disclosure and simplifying the description, instead of indicating or implying that the described structures or elements must have specific orientations, be constructed and be operated in specific orientations, and therefore cannot be understood as limitations of the embodiments of the present disclosure.

In the embodiments of the present disclosure, the terms “mount”, “connect”, and “connected” should be understood in a broad sense unless otherwise specified and defined. For example, each of them may refer to a fixed connection, a detachable connection, or an integral connection; each of them may refer to a mechanical connection or an electrical connection; each of them may refer to a direct connection or an indirect connection through an intermediate medium. For those of ordinary skill in the art, the specific meanings of the above terms in the embodiments of the present disclosure can be understood according to specific situations.

The embodiments of the present disclosure provide a display substrate including a base substrate and a metal wire grating layer on the base substrate, the metal wire grating layer is divided into a plurality of metal wire grating units, and polarization directions of the plurality of metal wire grating units are different.

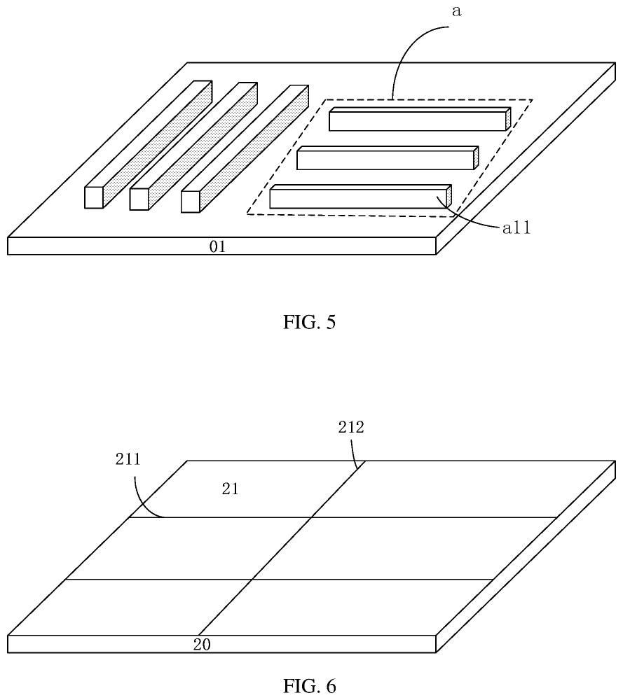

The metal wire grating layer is a polarizing element made of a metal material. Each metal wire grating unit has a plurality of metal wires which are parallel to each other, and the metal wire grating unit is used to perform filtration on light passing the metal wire grating unit so that light having a polarization direction perpendicular to an extension direction of the plurality of metal wires penetrates through the metal wire grating unit. Each metal wire grating unit has, for example, one or more slits, which are respectively located between adjacent metal wires. The slits belonging to the same metal wire grating unit have a same length direction. For example, as shown in FIG. 5, the metal wire grating layer is located on the base substrate 01 and includes a plurality of metal wire grating units a, and each metal wire grating unit a has a plurality of metal wires a11 parallel to each other.

For example, the polarization direction of each metal wire grating unit is determined by the extension direction of the metal wires included in the metal wire grating unit. For example, “the polarization directions of the plurality of metal wire grating units are different” means that the extension direction of the metal wires included in at least one metal wire grating unit is different from the extension direction of the metal wires included in the other metal wire grating units.

For example, “the polarization directions of the plurality of metal wire grating units are different” includes the following situations: (1) a part of the plurality of metal wire grating units have a same first polarization direction, another part of the plurality of metal wire grating units have a same second polarization direction, and the first polarization direction is different from the second polarization direction; and (2) any two metal wire grating units among the plurality of metal wire grating units have different polarization directions.

The metal wire grating layer has advantages of simple production process, short production time and low production cost. Therefore, the display substrate using the metal wire grating layer also has the advantages of simple production process, short production time and low production cost.

A material of the metal wire grating layer can be various. For example, the material of the metal wire grating layer is aluminum, silver, gold or the like. There are various manufacturing processes of the metal wire grating layer, such as a sputtering film formation process combining an etching process. The specific structure and size of the metal wire grating layer can be set according to the actual situation. For example, a thickness of the metal wire grating layer is from 50 nm to 200 nm, a width of the slit formed between two adjacent metal wires is from 100 nm to 300 nm, and a width of each metal wire is from 100 nm to 200 nm. The manufacturing process and structure size of the metal wire grating layer can be set according to the actual process.

There are many ways to divide the metal wire grating layer into the plurality of metal wire grating units. Under the condition that the polarization directions of the plurality of metal wire grating units are different, a division method of the metal wire grating layer and the polarization direction of each metal wire grating unit can be set according to the actual conditions, so as to meet the needs of the display substrate on different polarization directions.

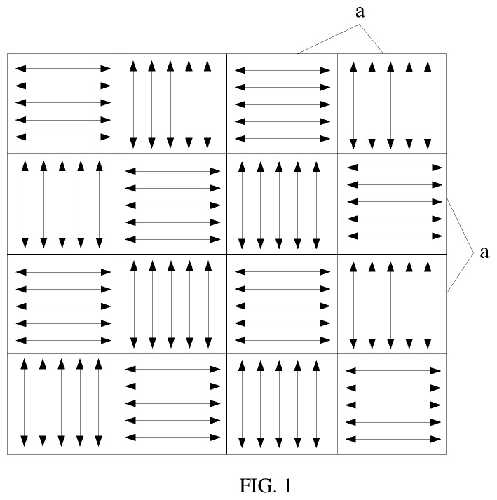

For example, the plurality of metal wire grating units are arranged in an array, and the polarization direction of each metal wire grating unit is different from the polarization direction of the adjacent metal wire grating unit that each metal wire grating unit is adjacent to. For example, the plurality of metal wire grating units of the metal wire grating layer having such a structure have two polarization directions. The polarization direction of each metal wire grating unit and the polarization direction of the adjacent metal wire grating unit that each metal wire grating unit is adjacent to can be set according to the actual situation. For example, the polarization direction of each metal wire grating unit and the polarization direction of the adjacent metal wire grating unit that each metal wire grating unit is adjacent to are perpendicular to each other or constitute an acute angle. For example, the polarization direction of each metal wire grating unit is perpendicular to the polarization direction of the adjacent metal wire grating unit that each metal wire grating unit is adjacent to, at this time, the metal wire grating layer has a better polarization effect, and the display substrate using the metal wire grating layer has a better polarization effect. As shown in FIG. 1, the metal wire grating layer includes the plurality of metal wire grating units a, the direction of the arrow in the metal wire grating unit a is the polarization direction of the metal wire grating unit a, and the polarization direction of each metal wire grating unit a in FIG. 1 is perpendicular to the polarization direction of the adjacent metal wire grating unit a that each metal wire grating unit a is adjacent to.

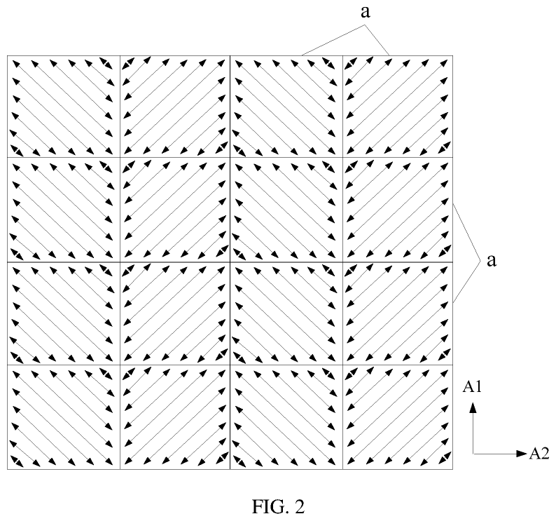

For example, the plurality of metal wire grating units are arranged in an array, the metal wire grating units in a first direction have a same polarization direction, adjacent metal wire grating units among the metal wire grating units in a second direction have different polarization directions, and the first direction is perpendicular to the second direction. For example, the plurality of metal wire grating units of the metal wire grating layer having such a structure have two polarization directions. For example, among the metal wire grating units in the second direction, the polarization directions of the adjacent metal wire grating units are perpendicular to each other or constitute an acute angle. For example, among the metal wire grating units in the second direction, the polarization directions of the adjacent metal wire grating units are perpendicular to each other, at this time, the metal wire grating layer has a better polarization effect, and the display substrate using the metal wire grating layer has a better polarization effect. As shown in FIG. 2, the metal wire grating layer includes the plurality of metal wire grating units a, the arrow direction in the metal wire grating unit a is the polarization direction of the metal wire grating unit a, the metal wire grating units a in the first direction A1 have the same polarization direction, and the polarization directions of any two adjacent metal wire grating units a among the metal wire grating units a in the second direction A2 are perpendicular to each other.

For example, as shown in FIG. 1, the polarization direction of each metal wire grating unit a is parallel or perpendicular to a horizontal direction.

For example, as shown in FIG. 2, the polarization direction of each metal wire grating unit a is at a position of constituting an acute angle with respect to the horizontal direction so that the polarization direction of each metal wire grating unit a is neither perpendicular nor parallel to the horizontal direction.

What described above are only examples of the division and polarization directions of the plurality of metal wire grating units of the metal wire grating layer. It can be set according to the actual situation, and any applicable division and polarization directions can be used.

The display substrate for example includes other metal wires. For example, in a situation where the display substrate is an array substrate of a liquid crystal display panel, the array substrate includes metal wires such as data wires and gate wires, and the metal wires that are originally designed and formed on the display substrate and the metal wire grating layer are for example formed through one patterning process, thereby simplifying the manufacturing processes of the metal wire grating layer and the display substrate. For example, the metal wire grating layer and the data wires are disposed in a same layer, and are formed through one patterning process. For example, the metal wire gate layer and the gate wires are disposed in a same layer, and are formed through one patterning process. For example, the display substrate is the array substrate, the gate wires of the array substrate are perpendicular to the data wires of the array substrate, and the metal wires in the metal wire grating layer can be set according to the distributions of the data wires and the gate wires of the array substrate. For example, among the plurality of metal wire grating units, the extension direction of the metal wires in a part of the plurality of metal wire grating units is parallel to the gate wires, and the extension direction of the metal wires in another part of the plurality of metal wire grating units is parallel to the data wires.

The embodiments of the present disclosure further provide a display panel including a first display substrate and a second display substrate, each of the first display substrate and the second display substrate is the display substrate described above, and the first display substrate and the second display substrate are opposite to each other and are bonded to each other. Orthographic projections of the plurality of metal wire grating units of the first display substrate on the second display substrate respectively overlap the plurality of metal wire grating units of the second display substrate in a one-to-one manner, and the polarization directions of the metal wire grating unit of the first display substrate and the metal wire grating unit of the second display substrate which directly face each other are perpendicular to each other.

Each of the first display substrate and the second display substrate has the structure and performance of the display substrate provided by the embodiments of the present disclosure. For example, the first display substrate includes a first base substrate and a first metal wire grating layer formed on the first base substrate, the first metal wire grating layer is divided into a plurality of first metal wire grating units, and the plurality of first metal wire grating units have different polarization directions. For example, the second display substrate includes a second base substrate and a second metal wire grating layer formed on the second base substrate, the second metal wire grating layer is divided into a plurality of second metal wire grating units, and the plurality of second metal wire grating units have different polarization directions.

Because the display panel includes the first display substrate and the second display substrate which are opposite to each other and are boned to each other, and the polarization directions of the metal wire grating unit of the first display substrate and the metal wire grating unit of the second display substrate which directly face each other are perpendicular to each other, the display panel can polarize light incident on the display panel so that the light emitted from the display panel has different polarization directions.

The metal wire grating layer has a linear polarization function so that light passing through the metal wire grating layer has a linear polarization direction; the display substrate using the metal wire grating layer has a linear polarization function, and the display panel including the display substrate also has a linear polarization function.

The type of the display substrate included in the display panel can be set according to the actual situation. For example, the first display substrate is a color filter substrate. The color filter substrate further includes a black matrix and a color filter layer, the color filter layer includes a plurality of color filter units arranged in an array, each color filter unit of the color filter layer is disposed in a color filter region surrounded by the black matrix, and orthographic projections of the plurality of color filter units on the metal wire grating layer respectively overlap the plurality of metal wire grating units of the metal wire grating layer in one-to-one manner. In the color filter substrate described above, a size of the metal wire grating unit of the substrate is divided according to a size of the color filter unit. For example, the black matrix, the color filter layer and the metal wire grating layer are disposed on a same side of a base substrate of the color filter substrate, and the plurality of color filter units of the color filter layer respectively cover the plurality of metal wire grating units of the metal wire grating layer. For example, the black matrix and the color filter layer are disposed on a first side of the base substrate of the color filter substrate, the metal wire grating layer is disposed on a second side of the base substrate of the color filter substrate, and the first side and the second side are opposite to each other side. For example, the first side of the base substrate of the color filter substrate faces the second display substrate.

In a situation where the first display substrate is the color filter substrate as described above, the second display substrate is, for example, an array substrate. The array substrate further includes a pixel layer, the pixel layer includes a plurality of pixel units arranged in an array, and orthographic projections of the plurality of pixel units on the metal wire grating layer overlap the plurality of metal wire grating units of the metal grating layer in one-to-one manner. In the above-mentioned array substrate, the size of the metal wire grating unit of the substrate is divided according to a size of the pixel unit. For example, the pixel layer and the metal wire grating layer are formed on a same side of a base substrate of the array substrate, and the plurality of pixel units of the pixel layer respectively cover the plurality of metal wire grating units of the metal wire grating layer. For example, the pixel layer is disposed on a first side of the base substrate of the array substrate, the metal wire grating layer is disposed on a second side of the base substrate of the array substrate, and the first side and the second side are opposite to each other. For example, the first side of the base substrate of the array substrate faces the first display substrate.

The display panel formed by the color filter substrate and the array substrate for example is a liquid crystal display panel. In a situation where the plurality of metal wire grating units belonging to the color filter substrate have two polarization directions and the plurality of metal wire grating units belonging to the array substrate have two polarization directions, the display panel has two kinds of linear polarization functions, and the light emitted from the liquid crystal display panel has two polarization directions to form a 3D image.

For example, the above-mentioned liquid crystal display panel is used together with special glasses. One lens of the glasses has one polarization direction, which is the same as one polarization direction of the light emitted from the liquid crystal display panel, and the other lens of the glasses has another polarization direction, which is the same as the other polarization direction of the light emitted from the display panel. The user wears the special glasses so that two eyes of the user receive light having two polarization directions, which is then synthesized into a 3D stereoscopic image by the human brain.

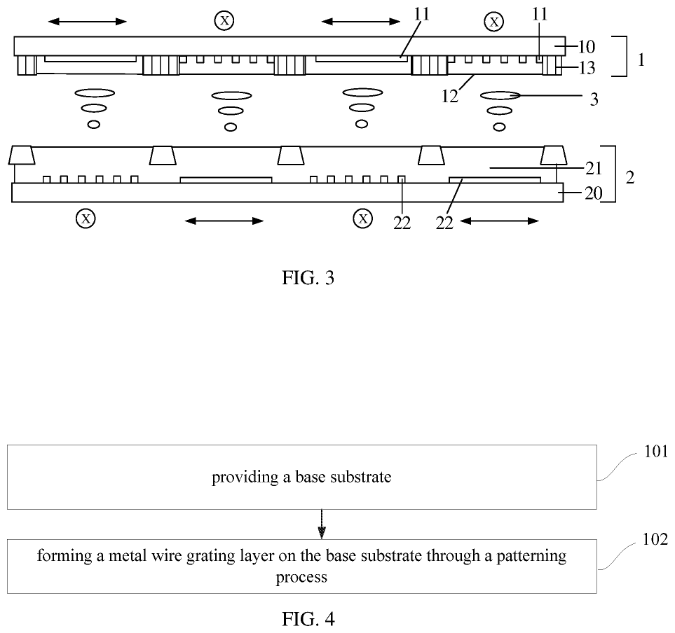

By way of example, FIG. 3 provides a schematic structural diagram of the liquid crystal display panel. The bidirectional arrow symbol in FIG. 3 indicates that the polarization direction of the metal wire grating unit is a left-right direction, and the symbol \textcircled{x} indicates that the polarization direction of the metal wire grating unit is an inside-outside direction.

Referring to FIG. 3, the liquid crystal display panel includes the color filter substrate 1, the array substrate 2 and a liquid crystal layer 3, and the liquid crystal layer 3 is disposed between the color filter substrate 1 and the array substrate 2.

The color filter substrate 1 includes the first base substrate 10, the first metal wire grating layer and the color filter layer. The first metal wire grating layer is divided into the plurality of first metal wire grating units, the plurality of first metal wire grating units are arranged in an array, and each first metal wire grating unit includes the plurality of metal wires 11 parallel to each other. The color filter layer is divided into the plurality of color filter units 12, and the orthographic projections of the plurality of first metal wire grating units on the color filter layer respectively overlap the plurality of color filter units 12 in one-to-one manner. The polarization direction of each first metal wire grating unit and the polarization direction of the adjacent first metal wire grating unit that each first metal wire grating unit is adjacent to are perpendicular to each other. The color filter substrate 1 further includes the black matrix 13 disposed on the first base substrate 10, and each color filter unit 12 of the color filter layer is disposed in the color filter region surrounded by the black matrix 13.

The array substrate 2 includes the second base substrate 20, the second metal wire grating layer and the pixel layer. The second metal wire grating layer is divided into the plurality of second metal wire grating units, the plurality of second metal wire grating units are arranged in an array, and each of the plurality of second metal wire grating units includes the plurality of metal wires 22 parallel to each other. The pixel layer is divided into the plurality of pixel units 21, and the orthographic projections of the plurality of second metal wire grating units on the pixel layer respectively overlap the plurality of pixel units 21 in one-to-one manner. The polarization direction of each second metal wire grating unit is perpendicular to the polarization direction of the adjacent second metal wire grating unit that each second metal wire grating unit is adjacent to; the polarization direction of the first metal wire grating unit is perpendicular to the polarization direction of the second metal wire grating unit which directly faces the first metal wire grating unit. In a situation where the color filter substrate 1 and the array substrate 2 have the pattern design shown in FIG. 3, the liquid crystal display panel has a better 3D display effect.

For example, FIG. 6 shows a schematic distribution diagram of the plurality of pixel units 21. The plurality of gate wires 211 and the plurality of data wires 212 are provided on the second base substrate 20, the plurality of gate wires 211 and the plurality of data wires 212 cross each other to define the plurality of pixel units 21, and the plurality of pixel units 21 are arranged in an array.

For the structure of each display substrate in the display panel, reference may be made to the above description of the display substrate in the embodiments of the present disclosure, and details are not described herein. The display panel provided by the embodiments of the present disclosure has the advantages of the display substrate provided by the embodiments of the present disclosure. The display panel has the advantages of simple production process, short production time, and low production cost.

In a conventional technology, a layer of polarizer with two polarization directions is attached to each of a light incident side and a light emitting side of the display panel, the attachment accuracy of the polarizer can only meet millimeter level, and cannot meet micron level which is required by the pixel design of the display panel, causing that the display performance of the display panel to which the polarizer is attached is decreased. The embodiments of the present disclosure use the metal wire grating layer as the polarizing element, instead of attaching the polarizer as described above in the conventional technology; because the metal wire grating layer can be made through various processes such as an etching process, and has the advantages of high manufacturing process accuracy and the like, the display performance of the display panel is improved by using the metal wire grating layer in the display panel.

The embodiments of the present disclosure further provide a display device including the display panel provided above in the embodiments of the present disclosure. The display device has the advantages of the display panel, which is not repeated here.

The embodiments of the present disclosure further provide a manufacturing method of the display substrate provided by the embodiments of the present disclosure. As shown in FIG. 4, the manufacturing method of the display substrate includes the following steps.

Step 101: providing the base substrate.

For example, in this step, the base substrate is selected or manufactured. The base substrate may be a substrate made of any suitable material, such as a glass substrate, a resin substrate, or the like. The type and size of the base substrate can be set according to the actual situation.

Step 102: forming the metal wire grating layer on the base substrate through a patterning process.

The metal wire grating layer has a metal layer structure and can be formed on the base substrate in various ways. For example, a metal film is firstly formed on the base substrate by a sputtering method, and then the metal film is patterned by using an etching process to form the metal wire grating layer having the desired polarization function.

According to the method provided by the embodiments of the present disclosure, the display substrate having the advantages such as simple production process, short production time, low production cost and good display performance is manufactured.

What are described above is related to the illustrative embodiments of the disclosure only and not limitative to the scope of the disclosure; the scopes of the disclosure are defined by the accompanying claims.

1. A display substrate, comprising a base substrate and a metal wire grating layer on the base substrate, wherein the metal wire grating layer comprises a plurality of metal wire grating units, and polarization directions of the plurality of metal wire grating units are different.

2. The display substrate according to claim 1, wherein the plurality of metal wire grating units are arranged in an array, and the polarization direction of each metal wire grating unit is different from the polarization direction of an adjacent metal wire grating unit that each metal wire grating unit is adjacent to.

3. The display substrate according to claim 2, wherein the polarization direction of each metal wire grating unit is perpendicular to the polarization direction of the adjacent metal wire grating unit that each metal wire grating unit is adjacent to.

4. The display substrate according to claim 1, wherein the plurality of metal wire grating units are arranged in an array, the metal wire grating units in a first direction have a same polarization direction, adjacent metal wire grating units among the metal wire grating units in a second direction have different polarization directions, and the first direction and the second direction are perpendicular to each other.

5. The display substrate according to claim 4, wherein the polarization directions of the adjacent metal wire grating units among the metal wire grating units in the second direction are perpendicular to each other.

6. The display substrate according to claim 1, wherein the polarization direction of each metal wire grating unit is parallel or perpendicular to a horizontal direction.

7. The display substrate according to claim 1, wherein the polarization direction of each metal wire grating unit is at a position of constituting an acute angle with respect to a horizontal direction.

8. A display panel, comprising a first display substrate and a second display substrate which are opposite to each other and are bonded to each other, wherein
each of the first display substrate and the second display substrate is the display substrate according to claim 1; and
orthographic projections of the plurality of metal wire grating units of the first display substrate on the second display substrate respectively overlap the plurality of metal wire grating units of the second display substrate in a one-to-one manner, and the polarization directions of the metal wire grating unit of the first display substrate and the metal wire grating unit of the second display substrate which directly face each other are perpendicular to each other.

9. The display panel according to claim 8, wherein
the first display substrate is a color filter substrate, the color filter substrate further comprises a black matrix and a color filter layer, the color filter layer comprises a plurality of color filter units arranged in an array, and each color filter unit of the color filter layer is in a color filter region surrounded by the black matrix; and
orthographic projections of the plurality of color filter units on the metal wire grating layer respectively overlap the plurality of metal wire grating units in a one-to-one manner.

10. The display panel according to claim 9, wherein the black matrix, the color filter layer and the metal wire grating layer are on a same side of the color filter substrate, and the plurality of color filter units of the color filter layer respectively cover the plurality of metal wire grating units of the metal wire grating layer.

11. The display panel according to claim 9, wherein the black matrix and the color filter layer are on a first side of the color filter substrate facing the second display substrate, the metal wire grating layer is on a second side of the color filter substrate, and the first side and the second side are opposite sides.

12. The display panel according to claim 8, wherein
the second display substrate is an array substrate, the array substrate further comprises a pixel layer, the pixel layer comprises a plurality of pixel units arranged in an array, and orthographic projections of the plurality of pixel units on the metal wire grating layer respectively overlap the plurality of metal wire grating units in a one-to-one manner.

13. The display panel according to claim 12, wherein the pixel layer and the metal wire grating layer are on a same side of the array substrate, and the plurality of pixel units of the pixel layer respectively cover the plurality of metal wire grating units of the metal wire grating layer.

14. The display panel according to claim 12, wherein the pixel layer is on a first side of the array substrate facing the first display substrate, the metal wire grating layer is on a second side of the array substrate, and the first side and the second side are opposite sides.

15. The display panel according to claim 13, wherein
the array substrate further comprises a plurality of gate wires and a plurality of data wires, the plurality of gate wires and the plurality of data wires cross each other to define the plurality of pixel units, and
the metal wire grating layer is in a layer where the plurality of gate wires or the plurality of data wires are located.

16. The display panel according to claim 15, wherein among the plurality of metal wire grating units of the array substrate, an extension direction of metal wires in a part of the plurality of the metal wire grating units is parallel to the plurality of gate wires, and an extension direction of metal wires in another part of the plurality of the metal wire grating units is parallel to the plurality of data wires.

17. A display device, comprising the display panel according to claim 8.

18. A manufacturing method of the display substrate according to claim 1, comprising:
providing the base substrate; and
forming the metal wire grating layer on the base substrate through a patterning process.

19. The display substrate according to claim 2, wherein the polarization direction of each metal wire grating unit is parallel or perpendicular to a horizontal direction.

20. The display substrate according to claim 4, wherein the polarization direction of each metal wire grating unit is at a position of constituting an acute angle with respect to a horizontal direction.
